(19) United States
(12) Patent Application Publication
(10) Pub. No.: US 2026/0282347 A1
(43) Pub. Date: Sep. 17, 2026

(54) METHODS OF FORMING MICROELECTRONIC DEVICES INCLUDING STAIRCASE STRUCTURES, AND RELATED MICROELECTRONIC DEVICES

(71) Applicant: Micron Technology, Inc., Boise, ID (US)

(72) Inventors: Martin J. Barclay, Middleton, ID (US); Yiping Wang, Boise, ID (US); Mojtaba Asadirad, Boise, ID (US); David H. Wells, Boise, ID (US); Darwin A. Clampitt, Wilder, ID (US)

(21) Appl. No.: 19/537,377

(22) Filed: Feb. 11, 2026

Related U.S. Application Data
(60) Provisional application No. 63/770,208, filed on Mar. 11, 2025.

(51) Int. Cl. H10B 41/27; H10B 41/50; H10B 43/50

(52) U.S. Cl. CPC H10B 41/27; H10B 41/50; H10B 43/50

(57) ABSTRACT

A method of forming a microelectronic device includes forming a staircase structure within an upper portion of a preliminary stack structure that comprises preliminary tiers respectively including insulative material and sacrificial vertically neighboring the insulative material. An oxide liner material is formed on steps of the staircase structure, and then additional staircase structure is formed within a lower portion of the preliminary stack structure. Implanted regions are formed within portions of the sacrificial material of the preliminary tiers of the lower group of the preliminary tiers proximate the additional steps of the additional staircase structure. The sacrificial material of the preliminary tiers is replaced with conductive material to form a stack structure. Conductive contacts are formed within the contact openings and vertically extending through an entire height of the stack structure. Additional conductive contacts are formed within horizontal areas of and vertically extending to the steps of the staircase structure.

### CROSS-REFERENCE TO RELATED APPLICATIONS

This application claims the benefit under 35 U.S.C. § 119(e) of U.S. Provisional Patent Application Ser. No. 63/770,208, filed Mar. 11, 2025, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices, such as Flash memory devices. A conventional Flash memory device generally includes a memory array having charge storage devices (e.g., memory cells, such as non-volatile memory cells) arranged in rows and columns. In a “three-dimensional NAND” memory device (which may also be referred to herein as a “3D NAND” memory device), not only are the memory cells arranged in row and column fashion in a horizontal array, but tiers of the horizontal arrays are stacked over one another (e.g., as vertical strings of memory cells) to provide a “three-dimensional array” of the memory cells. The stack structure of tiers vertically alternate conductive materials with insulative (e.g., dielectric) materials. The conductive materials function as control gates for access lines (e.g., word lines) of the memory cells. Vertical structures (e.g., pillars comprising channel structures and tunneling structures) extend along the vertical string of memory cells. A drain end of a string is adjacent one of the top and bottom of the vertical structure, while a source end of the string is adjacent the other of the top and the bottom of the pillar. The drain end is operably connected to a bit line, while the source end is operably connected to a source structure (e.g., a source plate, a source line). A 3D NAND memory device also includes electrical connections between the access lines and other conductive structures of the device so that the memory cells of the vertical strings can be selected for writing, reading, and erasing operations. For example, the 3D NAND memory device includes contact structures in electrical communication, by way of conductive routing structures, to additional contact structures that communicate to a source/drain region.

A continued goal in the microelectronic device fabrication industry is to reduce the footprint of the features of microelectronic devices so as to maximize the number of devices, and functional features thereof, in a given structural area. However, as device and feature sizes are reduced (e.g., scaled to smaller sizes) to accommodate a greater density of features, and as features are fabricated at the base of openings with higher aspect ratios, precise and accurate fabrication of structure features may be more challenging and may lead to fabrication errors. Accordingly, designing and fabricating 3D NAND memory devices continues to present challenges.

### BRIEF DESCRIPTION OF THE DRAWINGS

FIGS. 1 through 16 are simplified partial vertical cross-sectional views illustrating different processing stages of a method of forming a microelectronic device, in accordance with some embodiments of the disclosure;

FIG. 17 is a simplified, partial cutaway perspective view of a microelectronic device, in accordance with embodiments of the disclosure; and

FIG. 18 is a schematic block diagram of an electronic system, in accordance with embodiments of the disclosure.

### DETAILED DESCRIPTION

The following description provides specific details, such as material types, material thicknesses, and processing conditions in order to provide a thorough description of embodiments of the disclosure. However, a person of ordinary skill in the art will understand that embodiments of the present disclosure may be practiced without employing these specific details. Indeed, the embodiments of the present disclosure may be practiced in conjunction with conventional fabrication techniques employed in the industry. In addition, the description provided herein does not form a complete process flow for forming a semiconductor device structure, and the semiconductor device structures described below do not form a complete semiconductor device. Only those process acts and structures necessary to understand the embodiments of the present disclosure are described in detail below. Additional acts to form the complete semiconductor device may be performed by conventional fabrication techniques.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. Furthermore, the drawings accompanying the application are for illustrative purposes only, and are thus not necessarily drawn to scale. Elements common between figures may retain the same numerical designation. While the materials described and illustrated herein may be formed as layers, the materials are not limited thereto and may be formed in other three-dimensional configurations.

As used herein, the singular forms “a,” “an,” and “the” are intended to include the plural forms as well, unless the context clearly indicates otherwise.

As used herein, “and/or” includes any and all combinations of one or more of the associated listed items.

As used herein, relational terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., materials, structures, regions, circuitry, devices) described as “neighboring” one another means and includes features of the disclosed identity (or identities) that are located most proximate (e.g., closest to) one another. Additional features (e.g., additional regions, additional structures, additional regions, additional circuitry, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, reference to an element as being “on” or “over” another element means and includes the element being directly on top of, directly adjacent to (e.g., directly laterally adjacent to, directly vertically adjacent to), directly underneath, or in direct contact with the other element. It also includes the element being indirectly on top of, indirectly adjacent to (e.g., indirectly laterally adjacent to, indirectly vertically adjacent to), indirectly underneath, or near the other element, with other elements present therebetween. In contrast, when an element is referred to as being “directly on” or “directly adjacent to” another element, there are no intervening elements present.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, the term “about” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, any ordinal terms, such as “first,” “second,” etc., is used for clarity and convenience in understanding the disclosure and accompanying drawings or to distinguish one claimed construct from another, and do not connote or depend on any specific sequence, preference, time, uniqueness, or order, except where the context clearly indicates otherwise.

As used herein, “memory device” means and includes microelectronic devices exhibiting memory functionality, but not necessarily limited to memory functionality. Stated another way, and by way of example only, the term “memory device” means and includes not only memory (e.g., volatile memory, such as dynamic random access memory (DRAM); non-volatile memory, such as NAND memory), but also includes an application specific integrated circuit (ASIC) (e.g., a system on a chip (SoC)), an electronic device combining logic and memory, or a graphics processing unit (GPU) incorporating memory.

As used herein, “electronic device” includes, without limitation, a memory device, as well as a semiconductor device which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, “substrate” means and includes a base material or construction upon which additional materials are formed. The substrate may be, for example, a semiconductor substrate, a base semiconductor material on a supporting structure, a metal electrode or a semiconductor substrate having one or more materials, structures or regions formed thereon. The substrate may be a conventional silicon substrate, or other bulk substrate comprising a layer of semiconductive material. As used herein, the term “bulk substrate” means and includes not only silicon wafers, but also silicon-on-insulator (SOI) substrates, such as silicon-on-sapphire (SOS) substrates and silicon-on-glass (SOG) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. The substrate may be doped or undoped. By way of non-limiting example, a substrate may comprise at least one of silicon, silicon dioxide, silicon with native oxide, silicon nitride, a carbon-containing silicon nitride, glass, semiconductor, metal oxide, metal, titanium nitride, carbon-containing titanium nitride, tantalum, tantalum nitride, carbon-containing tantalum nitride, niobium, niobium nitride, carbon-containing niobium nitride, molybdenum, molybdenum nitride, carbon-containing molybdenum nitride, tungsten, tungsten nitride, carbon-containing tungsten nitride, copper, cobalt, nickel, iron, aluminum, and a noble metal.

As used herein, “conductive material” means and includes an electrically conductive material, such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). As used herein, an “insulative structure” means and includes a structure formed of and including one or more insulative materials. As used herein, an “dielectric structure” means and includes a structure formed of and including one or more dielectric materials.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlxZnySnzO), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, “removal selectivity” or “selectively removable” means that a material exhibits a greater removal rate upon exposure to a given removing (e.g., etching) chemistry and/or process conditions relative to another material exposed to the same removal chemistry and/or process conditions. For example, the material may exhibit a removal rate that is at least about five (5) times greater than the removal rate of another material, such as a removal rate of about 10 times greater, about 20 times greater, about 40 times greater, about 50 times greater, 75 times greater, about 100 times greater, or more than 100 times greater than the removal rate of the another material. Removal chemistries and conditions (e.g., etch chemistries and etch conditions) for selectively removing a material relative to one or more other materials may be selected by a person of ordinary skill in the art.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

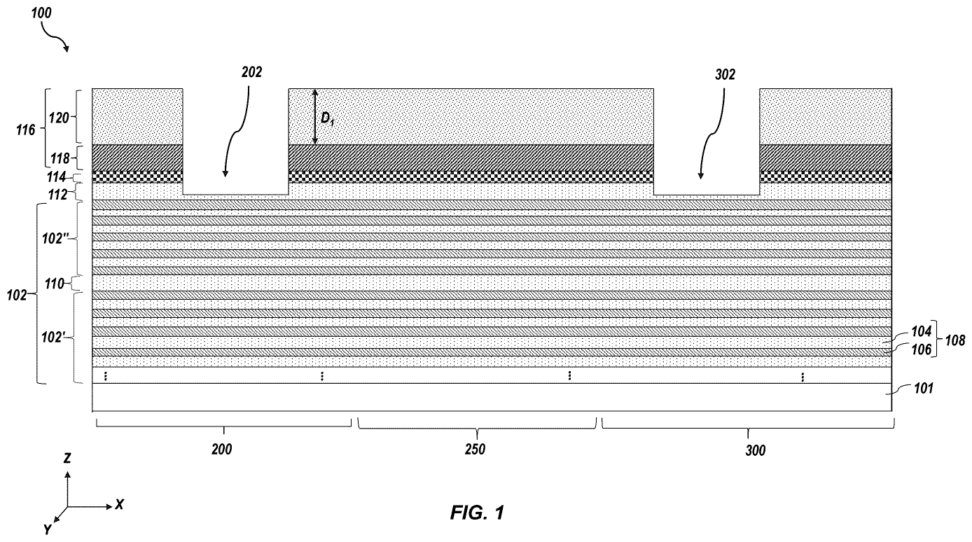

FIGS. 1 through 16 are simplified, partial vertical cross-sectional views of portions of a microelectronic device structure 100 (e.g., a memory device structure) at different processing stages for a method of forming a microelectronic device (e.g., a memory device, such as a 3D NAND Flash memory device), according to some embodiments of the disclosure. As described in further detail below, the method described with reference to FIGS. 1 through 16 may effectuate the formation of a microelectronic device having increased level of integration or density of features relative to conventional microelectronic devices. With the description provided below, it will be readily apparent to one of ordinary skill in the art that the methods and structures described herein with reference to FIGS. 1 through 16 may be used in the formation and configuration of various devices and electronic systems. The methods of the disclosure may be used whenever it is desired to form a microelectronic device.

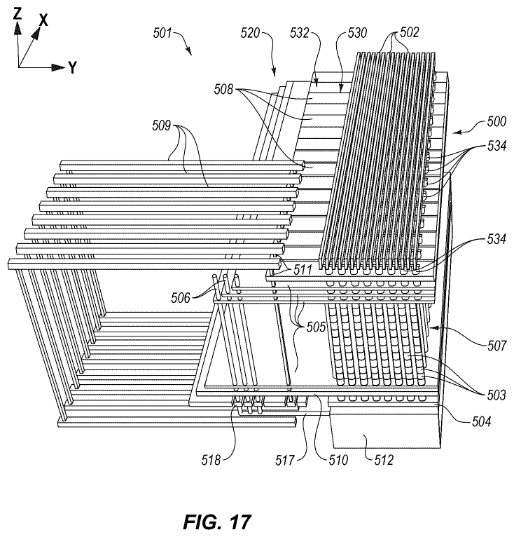

Referring to FIG. 1, the microelectronic device structure 100 may be formed to include a preliminary stack structure 102 vertically overlying (e.g., in the Z-direction) a substrate 101. The substrate 101 may, for example, include at least one source structure (e.g., source plate), as well as additional conductive structures (e.g., conductive routing structures, conductive interconnect structures, conductive contact structures). In some embodiments, the source structure within the substrate 101 is horizontally positioned within a memory array region of the microelectronic device structure 100 configured to contain vertically extending strings of memory cells (e.g., vertically extending strings of non-volatile memory cells, such as vertically extending strings of charge-trapping memory cells and/or vertically extending strings of floating-gate memory cells) therein. The source structure may be configured to be operatively associated with the vertically extending strings of memory cells subsequently formed within the memory array region, as described later in FIG. 17. In addition, at least some of the additional conductive structures within the substrate 101 may be positioned at a vertical elevation of the source structure and within a horizontal area of a staircase region (also referred to herein as a “contact region”) of the preliminary stack structure 102 that horizontally neighbors the array region.

The preliminary stack structure 102 may be formed to include a vertically alternating sequence of insulative material 104 and sacrificial material 106 (e.g., additional insulative material) arranged in preliminary tiers 108. Each of the preliminary tiers 108 of the preliminary stack structure 102 may include a level of the insulative material 104 vertically neighboring a level of the sacrificial material 106. Within the preliminary stack structure 102, the insulative material 104 may be vertically interleaved with the sacrificial material 106.

The insulative material 104 of the preliminary stack structure 102 may be formed of and include at least one insulative material having removal selectivity (e.g., etch selectivity) relative to the sacrificial material 106 of the preliminary stack structure 102. In some embodiments, the insulative material 104 is formed of and includes silicon oxide (e.g., SiO₂).

The sacrificial material 106 of the preliminary stack structure 102 may be formed of and include at least one material (e.g., at least one additional insulative material) that can be removed selectively relative to the insulative material 104 of the preliminary stack structure 102. As a non-limiting example, the sacrificial material 106 may be removed at etch rate that is at least two times (2×) faster than an etch rate of the insulative material 104 during mutual exposure to an etchant (e.g., a wet etchant). In some embodiments, the sacrificial material 106 is formed of and includes silicon nitride (e.g., Si₃N₄).

The preliminary stack structure 102 may be divided into a lower preliminary stack structure 102′ (e.g., a lower deck) and an upper preliminary stack structure 102″ (e.g., an upper deck) by an inter-deck structure 110 including insulative material. In some embodiments, the inter-deck structure 110 is formed of and includes SiOₓ (e.g., SiO₂).

Although FIG. 1 shows the lower preliminary stack structure 102′ and the upper preliminary stack structure 102″ to have certain levels of the insulative material 104 and the sacrificial material 106, the disclosure is not limited. Fewer or more levels of the insulative material 104 and/or the sacrificial material 106 may be included in the lower preliminary stack structure 102′ and/or the upper preliminary stack structure 102″ of the preliminary stack structure 102. A quantity of vertically alternating levels of the insulative material 104 and/or the sacrificial material 106 in the lower preliminary stack structure 102′ and/or the upper preliminary stack structure 102″ may, for example, be within a range from about two (2) to about one-thousand and twenty-four (1024). In some embodiments, the lower preliminary stack structure 102′ is formed to include the same quantity of preliminary tiers 108 as the upper preliminary deck structures 102″. In some embodiments, the lower preliminary stack structure 102′ is formed to include different quantity of preliminary tiers 108 (e.g., less preliminary tiers 108, more tiers 108) than the upper preliminary deck structure 102″. In some embodiments, the lower preliminary stack structure 102′ is formed to include a greater quantity of preliminary tiers 108 than the upper preliminary deck structures 102″.

A vertical stack of the lower preliminary stack structure 102′ and the upper preliminary stack structure 102″ is referred herein as a preliminary stack structure 102. Each level (e.g., vertical elevation) of the insulative material 104 and the sacrificial material 106 in the preliminary stack structure 102 may respectively have a desired vertical thickness. The levels of the insulative material 104 may have substantially the same vertical thickness as one another, or at least one level of the insulative material 104 may have a different vertical thickness than at least one other level of the insulative material 104. Furthermore, the levels of the sacrificial material 106 may have substantially the same vertical thickness as one another, or at least one level of the sacrificial material 106 may have a different thickness than at least one other level of the sacrificial material 106. In some embodiments, the insulative material 104 and the sacrificial material 106 respectively have a vertical thickness within a range of from about 10 nanometers (nm) to about 400 nm. In some embodiments, the insulative material 104 and the sacrificial material 106 respectively have a vertical thickness within a range of from about 10 nm to about 50 nm, such as from about 20 nm to about 50 nm.

Still referring to FIG. 1, the microelectronic device structure 100 may be formed to include a dielectric material 112 overlying an uppermost preliminary tier 108 of the preliminary stack structure 102. In some embodiments, the dielectric material 112 has a same material composition as the insulative material 104 of the preliminary tiers 108 and/or the inter-deck structure 110. In some embodiments, the dielectric material 112 is formed of and includes SiOₓ (e.g., SiO₂). In addition, a carbonitride material 114, such as silicon carbonitride (SiCN) may be formed over the dielectric material 112; and a sacrificial structure 116 may be formed over the carbonitride material 114. The sacrificial structure 116 may be formed to include a sacrificial polysilicon material 118 and a sacrificial oxide material 120. As shown in FIG. 1, the sacrificial oxide material 120 may vertically overlie and horizontally extend across the sacrificial polysilicon material 118. The sacrificial oxide material 120 has a vertical thickness D₁ (e.g., in Z-direction). In some embodiments, the vertical thickness D₁ of the sacrificial oxide material 120 is within a range of from about 500 nm to about 1000 nm, such as from about 600 nm to about 800 nm, or about 700 nm.

The microelectronic device structure 100 may include a memory array region and a staircase region horizontally (e.g., in the X-direction) neighboring the memory array region. The memory array region may include memory pillar structures (also referred to herein as “cell pillar structures”) employed to form portions of vertically extending strings of memory cells (e.g., vertically extending strings of non-volatile memory cells, such as vertically extending strings of charge-trapping memory cells and/or vertically extending strings of floating-gate memory cells), as described in further detail with reference to FIG. 17. Features within the memory array region of the microelectronic device structure 100 may be formed before, during (e.g., substantially simultaneous with), or after formation of features within the staircase region. The staircase region may include drain-side select gate (SGD) contact region 200 (also referred to herein as an “upper select gate region”), and a word line (WL) contact region 300 (also referred to herein as an “access line contact region”) horizontally neighboring (e.g., in the X-direction) the SGD contact region 200. The conductive contacts later formed within the SGD contact region 200 and the WL contact region 300 may electrically connect the memory cells later formed within the array region to other conductive features of the a microelectronic device of the disclosure. Furthermore, the microelectronic device structure 100 may include a bridging region 250 positioned horizontally (e.g., in the X-direction) between the SGD contact region 200 and the WL contact region 300.

With a continued referring to FIG. 1, a first trench 202 may be formed in the SGD contact region 200 extending vertically from the upper surface of the sacrificial oxide material 120 through the sacrificial structure 116 (the sacrificial oxide material 120 and the sacrificial polysilicon material 118), the carbonitride material 114, and at least a portion of the dielectric material 112. Although FIG. 1 is shown as including only one first trench 202 in the SGD contact region 200, the disclosure is not so limited, and the SGD contact region 200 may include more than one first trench 202 formed therein. An first additional trench 302 may be formed in the WL contact region 300 extending vertically from the upper surface of the sacrificial oxide material 120 through the sacrificial structure 116 (the sacrificial oxide material 120 and the sacrificial polysilicon material 118), the carbonitride material 114, and at least a portion of the dielectric material 112. Although FIG. 1 is shown as including only one first additional trench 302 in the WL contact region 300, the disclosure is not so limited, and the WL contact region 300 may include more than one first additional trench 302 formed therein.

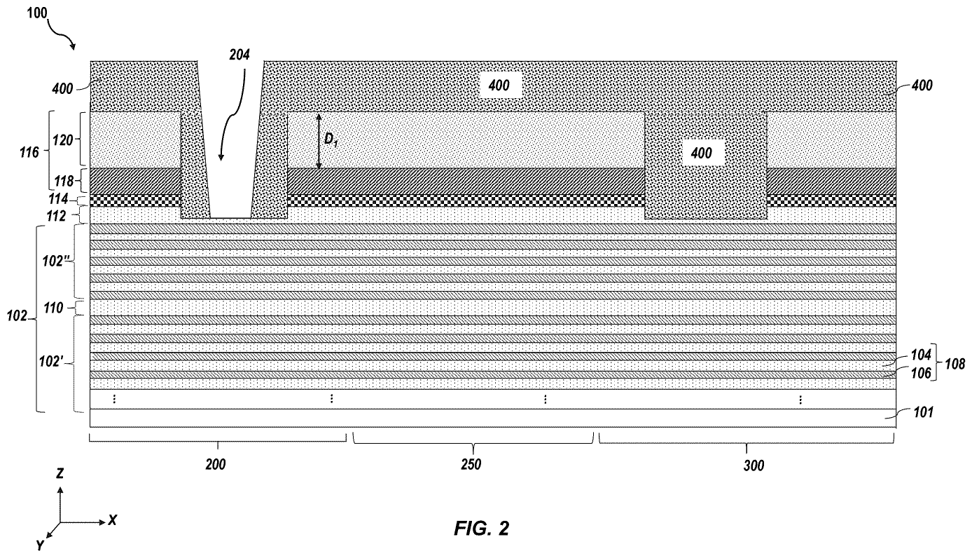

Referring next to FIG. 2, a first mask material 400 may be formed over the sacrificial oxide material 120, substantially filling the first trench 202 (FIG. 1) in the SGD contact region 200 and the first additional trench 302 (FIG. 1) in the WL contact region 300. After that, a portion of the first mask material 400 overlying the first trench 202 (FIG. 1) in the SGD contact region 200 may be removed to provide a second trench 204 extending vertically from the upper surface of the first mask material 400 through the sacrificial structure 116 (including the sacrificial oxide material 120 and the sacrificial polysilicon material 118 thereof), the carbonitride material 114, and at least a portion of the dielectric material 112.

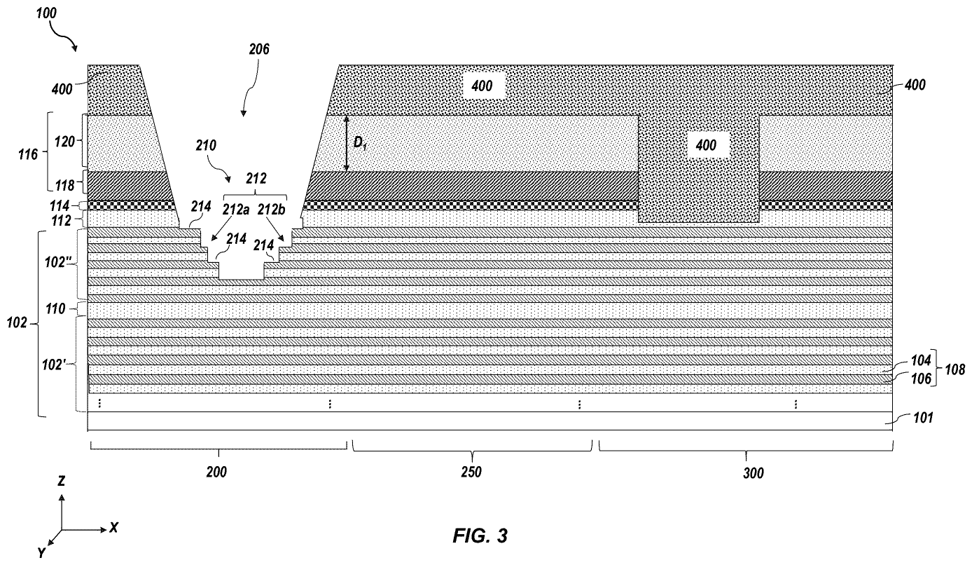

Referring next to FIG. 3, a third trench 206 may be formed through a series of etching acts effectuated on the second trench 204 (FIG. 2) and materials adjacent thereto. The third trench 206 may be relatively horizontally larger than the second trench 204 (FIG. 2), extending vertically into a portion of the preliminary stack structure 102 (e.g., the upper preliminary stack structure 102″). The third trench 206 may include a lower boundary defining a stadium structure 210 (also referred to herein as “SGD stadium structure”) formed within the upper preliminary stack structure 102″ in the SGD contact region 200 of the microelectronic device structure 100. The SGD stadium structure 210 may include staircase structures 212 (e.g., a first staircase structure 212a, and a second staircase structure 212b opposing the first staircase structure 212a) respectively having steps 214 defined by horizontal ends of some of the preliminary tiers 108 of the preliminary stack structure 102. The horizontal boundaries of an upper region of the third trench 206 may be defined by exposed sidewalls of the first mask material 400, the sacrificial structure 116 (including the sacrificial oxide material 120 and the sacrificial polysilicon material 118 thereof), and the carbonitride material 114. A lower region of the third trench 206 below the upper region may extend into the preliminary stack structure 102 may define a vertical cross-sectional profile of the SGD stadium structure 210. In some embodiments, the SGD stadium structure 210 extends vertically into at least a portions of the upper preliminary stack structure 102″ in the SGD contact region 200 of the microelectronic device structure 100. In some embodiments, the SGD stadium structure 210 extends vertically substantially through the upper preliminary stack structure 102″ within the SGD contact region 200 of the microelectronic device structure 100. Although FIG. 3 is shown as including only one SGD stadium structure 210 (and hence, only one third trench 206), the disclosure is not so limited, and multiple third trenches 206 (and hence, multiple third trenches 206) may be formed within the SGD contact region 200 of the microelectronic device structure 100.

For clarity and ease of understanding the drawings and associated description, FIG. 3 illustrates a particular quantity (e.g., four) of steps 214 in each of the staircase structures 212 of the SGD stadium structure 210. However, it will be understood that the staircase structures 212 of the SGD stadium structure 210 may respectively include a different quantity of steps 214 than those illustrated. For example, the staircase structures 212 of the SGD stadium structure 210 may individually include greater or equal to eight (8) of the steps 214.

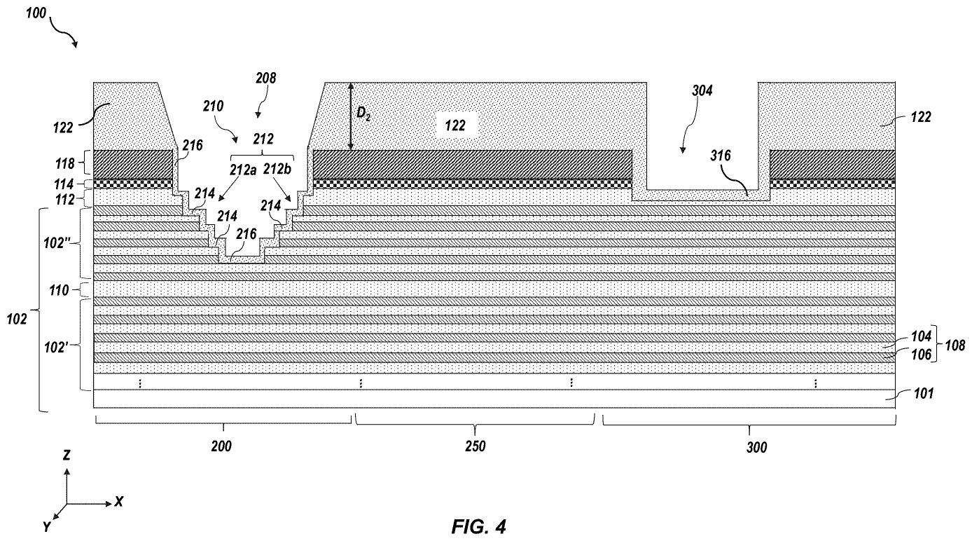

Referring next to FIG. 4, a portion of the first mask material 400 overlying the first additional trench 302 (FIG. 1) in the WL contact region 300 may be removed to provide a second additional trench extending vertically from the upper surface of the first mask material 400 through the sacrificial structure 116 (FIG. 3, including the sacrificial oxide material 120 and the sacrificial polysilicon material 118 thereof), the carbonitride material 114, and at least a portion of the dielectric material 112. The first mask material 400 is then removed, and an additional sacrificial oxide is formed over exposed materials of the microelectronic device structure 100. The additional sacrificial oxide may be formed to vertically overlie and cover the previously formed sacrificial oxide material 120 (FIG. 3), resulting in a sacrificial oxide material 122 in the SDG contact region 200, the bridging region 250, and the WL contact region 300. The sacrificial oxide material 122 may have an additional vertical thickness D₂ (e.g., in Z-direction), which is higher than the vertical thickness D₁ of the sacrificial oxide material 120 in FIG. 3. In some embodiments, the additional vertical thickness D₂ of the sacrificial oxide material 122 is within a range of from about 600 nm to about 1200 nm, such as from about 700 nm to about 1100 nm, from about 800 nm to about 1000 nm, or about 900 nm. An oxide liner 216 may be formed on or over exposed surfaces defining of the third trench 206 (FIG. 3) to form provide an lined third trench 208. Furthermore, an oxide liner 316 may be formed outlining the preliminary trench in the WL contact region 300 to provide a lined second additional trench 304. A material composition of the oxide liner 216 in the SGD contact region 200 and/or the oxide liner 316 in the WL contact region 300 may be substantially the same as or different than that of the sacrificial oxide material 122.

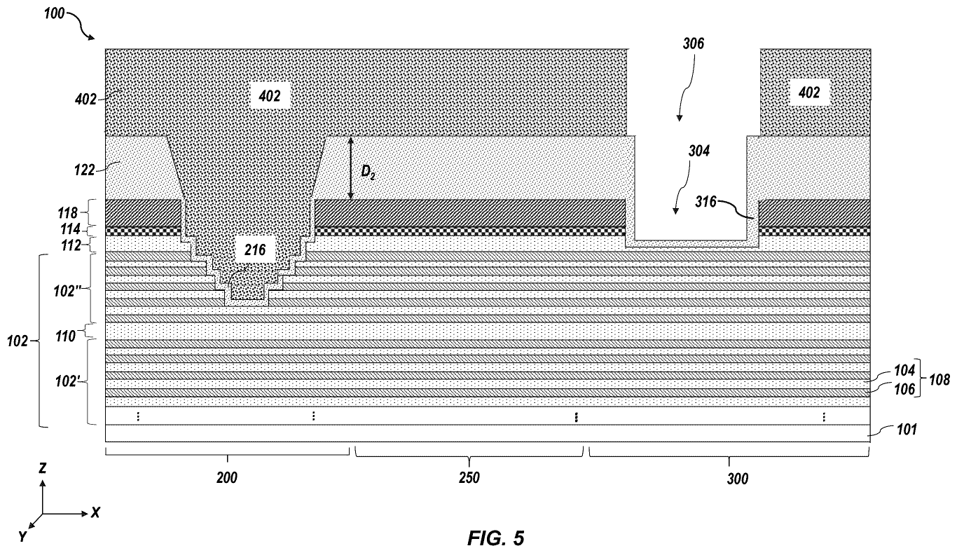

Referring next to FIG. 5, a second mask material 402 may be formed over the sacrificial oxide material 122, and may substantially fill the lined third trench 208 (FIG. 4) in the SGD contact region 200 and the lined second additional trench 304 (FIG. 4) in the WL contact region 300. Thereafter, a portion of the second mask material 402 within a horizontal area of the lined second additional trench 304 (FIG. 4) in the WL contact region 300 may be removed to create an opening 306 in the second mask material 402. Furthermore, a portion of the second mask material 402 within the lined second additional trench 304 may be removed by way of the opening 306 in the second mask material 402. The opening 306 of the second mask material 402 may be integral and continuous (e.g., unitary) with the lined second additional trench 304.

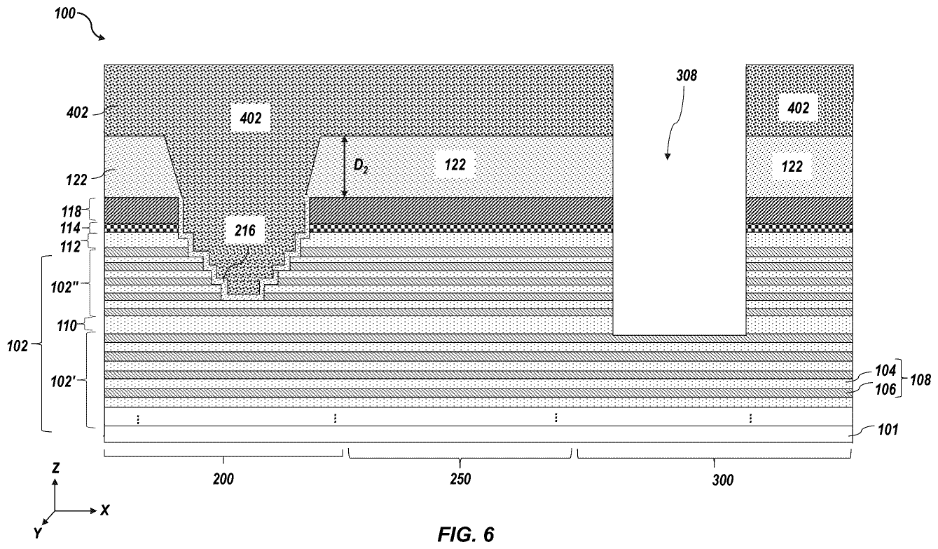

Referring next to FIG. 6, the oxide liner 316 and the portions of preliminary stack structure 102 vertically underlying and within a horizontal area of the opening 306 in the second mask material 402 may be removed to form a third additional trench 308. The third additional trench 308 extends vertically from the upper surface of the second mask material 402 through the sacrificial oxide material 122, the sacrificial polysilicon material 118, the carbonitride material 114, the dielectric material 112, the upper preliminary stack structure 102″, and the inter-deck structure 110. The third additional trench 308 may expose the sacrificial material 106 of an uppermost one of the preliminary tiers 108 of the lower preliminary stack structure 102′.

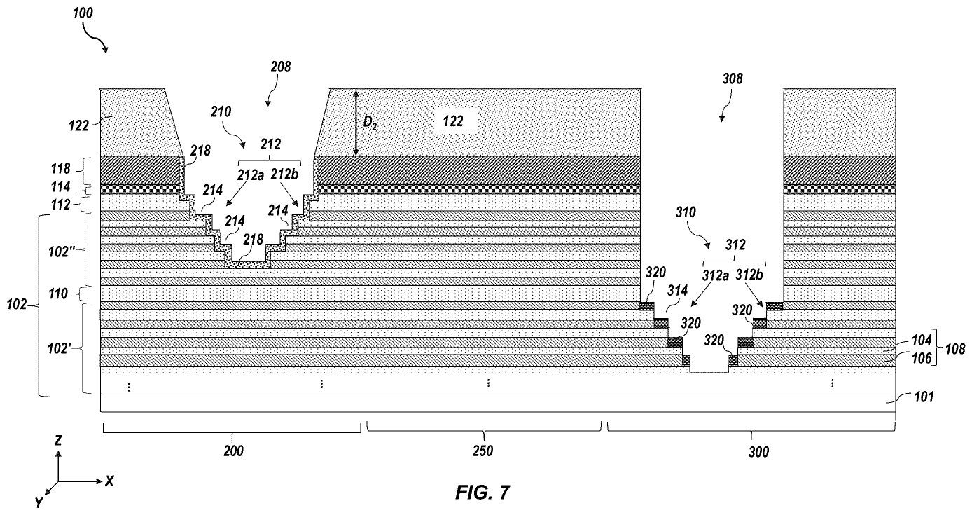

Referring next to FIG. 7, portions of the lower preliminary stack structure 102′ within an a horizontal area of the third additional trench 308 may be removed (e.g., trimmed, etched) by way of the third additional trench 308 to form an additional stadium structure 310 (also referred to herein as a “WL stadium structure”) in the WL contact region 300 of the microelectronic device structure 100. The additional stadium structure 310 may include additional staircase structures 312 (e.g., a first additional staircase structure 312a, and a second additional staircase structure 312b opposing the first additional staircase structure 312a) respectively having additional steps 314 defined by horizontal ends of at least some of the preliminary tiers 108 within the lower preliminary stack structure 102′. In addition, remaining portions of the second mask material 402 (FIG. 6) may be substantially removed to again form the lined third trench 208 in the SGD contact region 200.

Although FIG. 7 is shown as including only one additional stadium structure 310 (and, hence, only one third additional trench 308) within the WL contact region 300, the disclosure is not so limited; and there may be more multiple additional stadium structures 310 (and, hence, multiple third additional trenches 308) formed within the WL contact region 300. In some embodiments, multiple (e.g., more than one) additional stadium structures 310 are formed within the WL contact region 300 by way of multiple third additional trenches 308. In some embodiments, the additional stadium structures 310 are positioned at substantially the same vertical location as one another within the lower preliminary stack structure 102′. In additional embodiments, at least one of the additional stadium structures 310 is formed at different vertical location within the lower preliminary stack structure 102′ than at least one other of the additional stadium structures 310.

For clarity and ease of understanding the drawings and associated description, FIG. 7 illustrates a particular quantity (e.g., four) of additional steps 314 in each of the additional staircase structures 312 of the additional stadium structure 310. However, it will be understood that one or more of the additional staircase structures 312 of the additional stadium structure 310 may include a greater quantity of the additional steps 314 than those illustrated. For example, the additional staircase structures 312 of the additional stadium structure 310 may individually include greater or equal to eight (8) of the additional steps 314, greater than or equal to sixteen (16) of the additional steps 314, greater or equal to than thirty-two (32) of the additional steps 314, greater than or equal to sixty-four (64) of the additional steps 314, greater than or equal to one-hundred twenty-eight (128) of the additional steps 314, greater than or equal to two-hundred fifty-six (256) of the additional steps 314, greater than or equal to five-hundred twelve (512) of the additional steps 314, or greater than or equal to one-thousand twenty-four (1024) of the additional steps 314.

Still referring to FIG. 7, implanted regions 320 may be formed within the portions of the sacrificial material 106 of the preliminary tiers 108 partially defining the additional steps 314 of the additional staircase structures 312 of the additional stadium structure 310. The exposed portions of the sacrificial material 106 of the preliminary tiers 108 partially defining the additional steps 314 may be subjected to (e.g., exposed to) one or more treatment acts that change a material composition of the exposed portions of the sacrificial material 106 of the preliminary tiers 108. For example, the exposed portions of the sacrificial material 106 of the preliminary tiers 108 may be implanted with boron, carbon, oxygen, gallium, or a combination thereof. In some embodiments, each of the implanted regions comprises a concentration of the implanted material (e.g., boron, carbon, oxygen, gallium, or a combination thereof) within a range of from about 0.1 atomic % to about 25 atomic %. The material of the implanted regions 320 may, for example, be formed of and include one or more of carbon-containing material (e.g., carbon-doped silicon nitride (e.g., silicon carbon nitride (SiCN))), boron-containing material (e.g., boron-doped silicon nitride), or gallium-containing material. The treatment acts may change a material composition of the exposed portions of the sacrificial material 106 of the preliminary tiers 108 compared to a material composition of the unexposed portions of the sacrificial material 106 of the of the preliminary tiers 108. The implanted regions 320 may exhibit etch selectivity relative to the insulative material 104 of the preliminary stack structure 102, and, optionally, the non-implanted regions of the sacrificial material 106 of the preliminary tiers 108 of the preliminary stack structure 102.

The implanted regions 320 may be formed within the sacrificial material 106 of the preliminary tiers 108 partially defining the additional steps 314 of the additional staircase structures 312 of the additional stadium structure 310 without being formed within the sacrificial material 106 of others of the preliminary tiers 108 of the preliminary stack structure 102. During the one or more treatment acts, the sacrificial material 106 of others of the preliminary tiers 108 partially defining the steps 214 of the staircase structures 212 of the stadium structure 210 are protected by the oxide liner 216 (FIG. 6), and are not subjected to the implantation acts. However, during the one or more treatment acts, the exposed oxide liner 216 (FIG. 6) may be subjected to (e.g., exposed to) the one or more treatment acts that change a material composition of the oxide liner 216 in the SGD contact region 200 to a modified oxide liner material 218. For example, the exposed oxide liner 216 may be implanted with boron, carbon, oxygen, gallium, or a combination thereof. In some embodiments, the exposed oxide liner 216 comprises a concentration of the implanted material (e.g., boron, carbon, oxygen, gallium, or a combination thereof) within a range of from about 0.1 atomic % to about 25 atomic %.

In some embodiments, the implanted species of the implanted regions 320 is carbon, and after the implantation stage, the implanted regions 320 within the WL contact region 300 are respectively formed of and include carbonitride material (e.g., silicon carbonitride), and the modified oxide liner material 218 within the SGD contact region 200 is formed of and includes oxycarbide material (e.g., silicon oxycarbide).

Furthermore, during the one or more treatment acts, the bridging region 250 of the microelectronic device structure 100 is protected by the sacrificial oxide material 122, and therefore the bridging region 250 is not subjected to the implantation acts.

The treatment (e.g., implantation) conditions and dopant concentration may be tailored to achieve the desired etch selectivity of the insulative material 104 of the preliminary tiers 108 and other exposed materials relative to the implanted regions 320. For example, the treatment conditions may be formulated to achieve a desired etch selectivity of the implanted regions 320, such that material of the implanted regions 320 is selectively removable during material removal processes used to remove the sacrificial material 106 of the preliminary tiers 108, including remaining portions of the sacrificial material 106 of the preliminary tiers 108 horizontally adjacent to and vertically overlapping the implanted regions 320. Accordingly, the sacrificial material 106 of the preliminary tiers 108 and the material of the implanted regions 320 may be subsequently removed in a single processing act, responsive to the treatment conditions used to form the implanted regions 320. In additional embodiments, the material of implanted regions 320 exhibits etch electivity relative to the sacrificial material 106 of the preliminary tiers 108, such that the sacrificial material 106 and the material implanted regions 320 are subsequently removed in multiple (e.g., two or more) processing acts.

Referring next to FIG. 8, the sacrificial oxide material 122 (FIG. 7) and the sacrificial polysilicon material 118 (FIG. 7) may be removed, and insulative fill material 130 may be formed to at least partially (e.g., substantially) fill the lined third trench 208 within the SGD contact region 200, and the third additional trench 308 within the WL contact region 300. The insulative fill material 130 may be formed of and include a material exhibiting removal selectivity relative to one or more of the insulative material 104 of the preliminary tiers 108 of the preliminary stack structure 102, the sacrificial material 106 of the preliminary tiers 108 of the preliminary stack structure 102, and additional materials (e.g., additional insulative materials, additional conductive materials) formed during subsequent processing of the microelectronic device structure 100. In some embodiments, the insulative fill material 130 includes one or more of the insulative materials (e.g., silicon oxide) described above with reference to the insulative material 104 of preliminary tiers 108 of the preliminary stack structure 102. Uppermost boundaries (e.g., uppermost surfaces) of the insulative fill material 130 in the WL contact region 300 and the SGD contact region 200 may be formed (e.g., by way of a CMP process) to be substantially coplanar with an uppermost surface of the carbonitride material 114 overlying the preliminary stack structure 102.

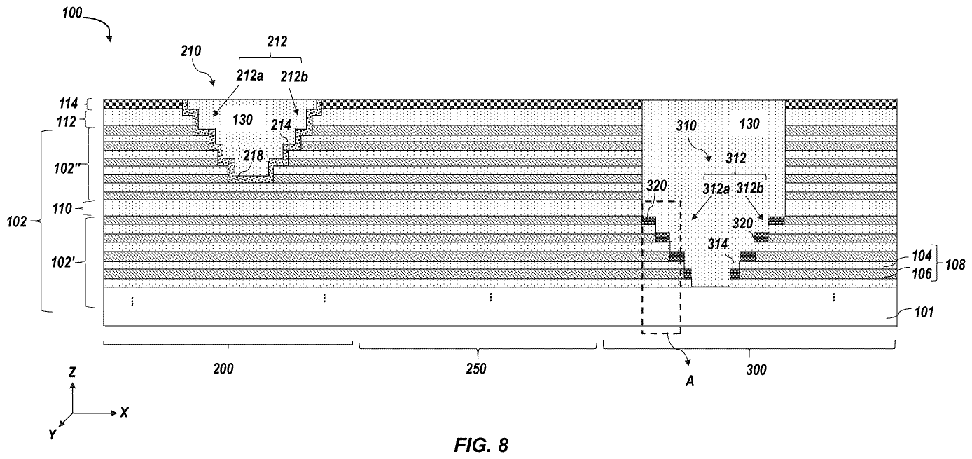

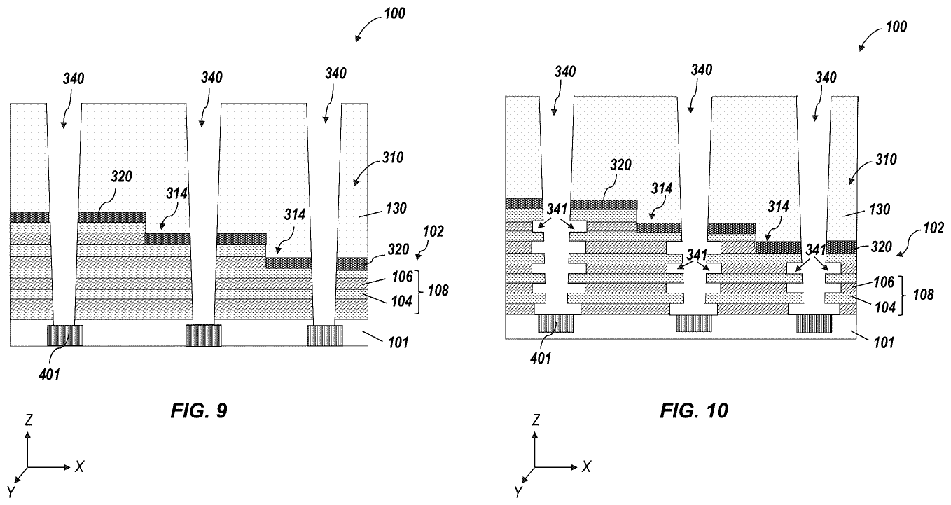

Referring next to FIG. 9, which illustrates an enlarged portion of dashed box A shown in FIG. 8 following the processing stage previously described with reference to FIG. 8, first contact openings 340 (also referred to herein as “WL contact openings”) may be formed to vertically extend from an upper surface of the insulative fill material 130 through an entire vertical extent (e.g., a height) of the preliminary stack structure 102. The first contact openings 340 may be positioned with a horizontal area of the additional stadium structure 310. For example, an individual first contact opening 340 may be formed to be horizontally positioned within a horizontal area of a tread of an individual step 314 of the additional stadium structure 310. To form the first contact openings 340, portions of each of the insulative fill material 130, the implanted regions 320, as well as the insulative material 104 and the sacrificial material 106 of some of the preliminary tiers 108 of the preliminary stack structure 102 may be removed by exposing the respective materials to wet etch chemistries and/or dry etch chemistries, for example, in one or more material removal processes. The first contact openings 340 each may be formed to vertically extend through the entire height (e.g., in the Z-direction) of the preliminary stack structure 102; therefore, a height of each of the first contact openings 340 in the vertical direction (e.g., in the Z-direction) may be substantially similar to (e.g., substantially the same as) one another irrespective of horizontal orientation relative to the additional steps 314 of the additional stadium structure 310. Manufacturing processes may be simplified by forming the first contact openings 340 to extend entirely through the vertical extent of the preliminary stack structure 102, without forming the first contact openings 340 to extend to varying (e.g., differing) depths corresponding to various locations of the individual additional steps 314 of the additional stadium structure 310.

In some embodiments, as shown in FIG. 9, the first contact openings 340 may be formed to extend from an upper surface of the insulative fill material 130 to conductive routing structures 401 vertically underlying the preliminary stack structure 102. The first contact openings 340 may be contact openings (e.g., word line contact openings, lower select line contact openings), which are employed in later processing stages to form contacts (e.g., word line contacts, lower select line contacts).

Horizontal dimensions of an individual first contact opening 340 may be relatively smaller than that of a tread of an individual step 314 of the additional stadium structure 310. For example, a width of the first contact openings 340 may be within a range of from about 100 nm to about 500 nm, such as from about 100 nm to about 150 nm, from about 150 nm to about 250 nm, from about 250 nm to about 350 nm, or from about 350 nm to about 500 nm. Horizontal dimensions of the first contact openings 340 may be selected and tailored to effect desirable geometric configurations (e.g., sizes and shapes) to features (e.g., contact structures) to be formed therein.

Referring next to FIG. 10, the lateral portion (e.g., in the X-direction, in the Y-direction) of the sacrificial material 106 of the preliminary tiers 108 of the preliminary stack structure 102 within a vertical span of the additional stadium structure 310 (FIG. 8) may be selectively removed through the first contact openings 340 to form lateral recesses 341. Each of the lateral recesses 341 is in communication with a respective one of the first contact openings 340, and may be defined vertically (e.g., in the Z-direction) by the insulative material 104 of two of the preliminary tiers 108 of the preliminary stack structure 102 within the vertical span of the additional stadium structure 310 (FIG. 8). By way of non-limiting example, portions of the sacrificial material 106 of the preliminary tiers 108 of preliminary stack structure 102 within the vertical span of the additional stadium structure 310 (FIG. 8) may be exposed to an etchant (e.g., a wet etchant) through the first contact openings 340 to selectively remove the portions of the sacrificial material 106 relative to the implanted regions 320 and the insulative material 104 of the preliminary tiers 108 of the preliminary stack structure 102 within the vertical span of the additional stadium structure 310 (FIG. 8). In some embodiments, the sacrificial material 106 of the preliminary tiers 108 within the vertical span of the additional stadium structure 310 (FIG. 8) is exposed to phosphoric acid (H₃PO₄) to selectively remove portions of the sacrificial material 106 proximate to the first contact openings 340.

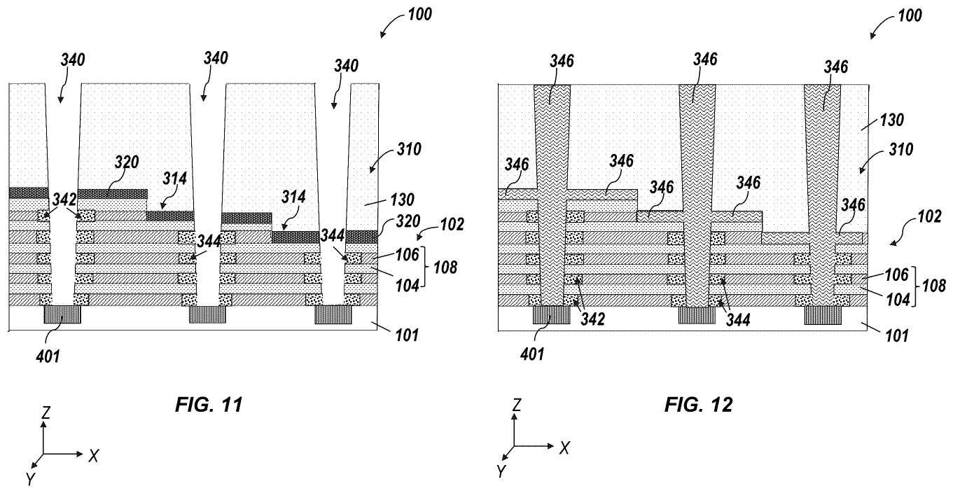

Referring next to FIG. 11, an insulative liner material 342 may be formed within the lateral recesses 341 (FIG. 10) without completely filling the first contact openings 340. For example, the insulative liner material 342 may be formed within the lateral recesses 341 to effectively “pinch off” and close (e.g., seal) the lateral recesses 341. The insulative liner material 342 may be formed by conventional techniques, such as one or more of in situ growth, CVD, ALD, and PVD using conventional processing equipment. In some embodiments, the insulative liner material 342 is formed (e.g., deposited) using a single, continuous ALD process or a single, continuous CVD process. Following the formation of the insulative liner material 342 within the lateral recesses 341 (FIG. 10), portions of the insulative liner material 342 outside of the lateral recesses 341 (FIG. 10) (e.g., within the first contact openings 340) may be removed (e.g., etched away) while maintained other portions of the insulative liner material 342 within the lateral recesses 341 (FIG. 10).

Alternatively, lateral (e.g., in the X-direction, in the Y-direction) portions of the sacrificial material 106 of the preliminary tiers 108 of the preliminary stack structure 102 within the vertical span of the additional stadium structure 310 (FIG. 8) and proximate to the first contact openings 340 may be converted to another insulative material to isolate remaining portions of the sacrificial material 106 of the preliminary tiers 108 from conductive contacts to be formed in a later processing stage. For example, the sacrificial material 106 (e.g., a silicon nitride material) of the preliminary tiers 108 of the preliminary stack structure 102 within the vertical span of the additional stadium structure 310 (FIG. 8) may be oxidized to form the insulative liner material 342. Accordingly, the insulative liner material 342 may be directly laterally adjacent to (e.g., continuous with) remaining portions of the sacrificial material 106 of the preliminary tiers 108 of the preliminary stack structure 102 within the vertical span of the additional stadium structure 310 (FIG. 8). In some such embodiments, the insulative liner material 342 is formed of and includes an oxide material having a material composition that differs from that of the remaining portions of the sacrificial material 106 of the preliminary tiers 108, although other materials of the insulative liner material 342 may be contemplated, so long as the insulative liner material 342 exhibits an etch selectivity relative to surrounding materials.

Formation of the insulative liner material 342 may result in formation of isolation regions 344 between the first contact openings 340 and the remaining portions of the sacrificial material 106 of the preliminary tiers 108 of the preliminary stack structure 102 within the vertical span of the additional stadium structure 310 (FIG. 8), such that portions of the sacrificial material 106 of the preliminary tiers 108 are isolated from the first contact openings 340 by the insulative liner material 342 of the isolation regions 344. Thus, processing acts may be selected to provide (e.g., facilitate, promote) formation of the insulative liner material 342 proximate the first contact openings 340 for formation of the isolation regions 344 intervening between the remaining portions of the sacrificial material 106 of the preliminary tiers 108 of the preliminary stack structure 102 within the vertical span of the additional stadium structure 310 (FIG. 8) and the first contact openings 340.

The insulative liner material 342 may be formed of and include one or more of the materials described above with reference to the insulative material 104 (e.g., SiO₂). For example, the insulative liner material 342 may be formed of and include insulative material that is different than, and that exhibits etch selectivity with respect to, the remaining sacrificial material 106 of the preliminary tiers 108 and the material of the implanted regions 320. In some embodiments, the insulative liner material 342 is formed of and includes a single high quality silicon oxide material, such as an ALD SiOₓ. For example, the insulative liner material 342 may be a substantially uniform and substantially conformal silicon oxide material (e.g., a substantially uniform and substantially conformal silicon dioxide material) so that is substantially free of voids therein. The insulative liner material 342 may, alternatively, be formed of and include one or more of silicon oxycarbide (SiOₓC_{y}), silicon oxynitride (SiOₓN_{y}), hydrogenated silicon oxycarbide (SiCₓO_{y}H_{z}), and silicon oxycarbonitride (SiOₓC_{y}N_{z}), for example.

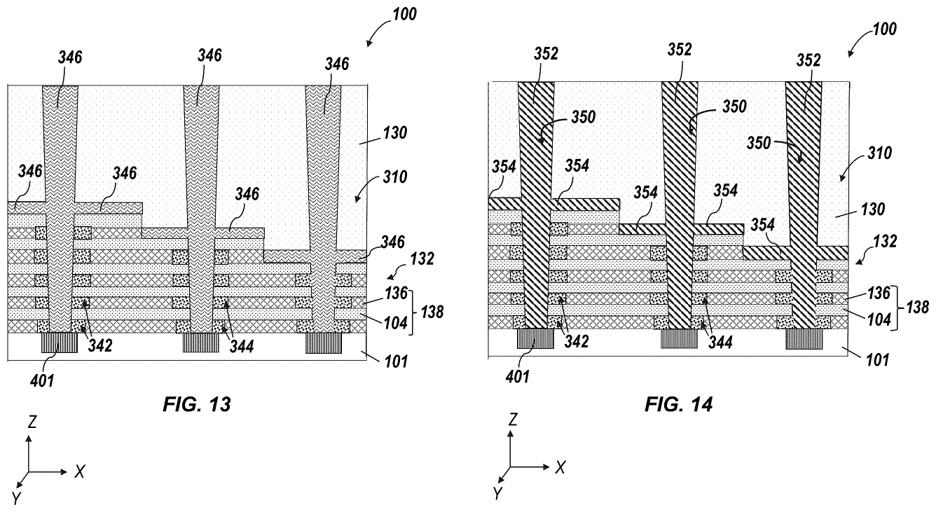

Referring next to FIG. 12, remaining portions of the material of the implanted regions 320 (FIG. 11) may, optionally, be selectively removed (e.g., exhumed) to form lateral openings that are integral and continuous (e.g., unitary) with the first contact openings 340. For example, portions of the implanted regions 320 overlying the additional steps 314 of the additional stadium structure 310 may be at least partially (e.g., substantially entirely) removed to form the lateral openings. In additional embodiments, portions of the implanted regions 320 remain within the horizontal area of the additional stadium structure 310 at the processing stage of FIG. 11, and are removed (e.g., exhumed) during subsequent material removal processes (e.g., replacement gate processing acts, as described with reference to FIG. 13).

In some embodiments, the material (e.g., carbon-containing material) of the implanted regions 320 is removed by exposing the material to one or more etchants, such as wet etchants, through the first contact openings 340. The wet etchants may include one or more of phosphoric acid, acetic acid, nitric acid, hydrochloric acid, aqua regia, or hydrogen peroxide. In some embodiments, the material of the implanted regions 320 is removed by a phosphoric acid/acetic acid/nitric acid (PAN) etch chemistry. However, the disclosure is not so limited and the material of the implanted regions 320 may be removed with other etchants and/or material removal processes (e.g., vapor phase removal processes, atomic layer removal processes). For example, the material of the implanted regions 320 may be removed by performing a sequence of self-limiting processes of an atomic layer removal process to modify a surface of a material (e.g., the implanted regions 320), followed by selective removal of the modified surface material. In additional embodiments, the material of the implanted regions 320 is removed by a plasma etching process (e.g., an inductively coupled plasma (ICP) etching process) comprising one or more of hydrogen fluoride (HF), nitrogen trifluoride (NF₃), sulfur hexafluoride (SF₆), carbon tetrafluoride (CF₄), and another material. The material of the implanted regions 320 may, optionally, be exposed to hydrogen (H₂), nitrogen (N₂), oxygen (O₂), argon (Ar), or a combination thereof. The material of the implanted regions 320 may, alternatively, be removed by exposure to one or more dry etchants.

Still referring to FIG. 12, a first sacrificial fill material 346 may, optionally, be formed within one or more of the first contact openings 340 (FIG. 11) and the associated lateral openings. In some embodiments, the first sacrificial material fill material 346 is conformally formed within the first contact openings 340 to be substantially continuous along a vertical dimension (e.g., a vertical height) of the preliminary stack structure 102, as well as within the associated lateral openings. In other embodiments, the first sacrificial fill material 346 is non-conformally formed within the first contact openings 340 and the associated lateral openings. Accordingly, the first sacrificial fill material 346 may be formed to include varying (e.g., uneven) thicknesses throughout the first contact openings 340 and the associated lateral openings. Further, the first sacrificial fill material 346 may be formed to include segmented (e.g., discontinuous) portions thereof, such that regions of the first contact openings 340 and the associated lateral openings include the first sacrificial fill material 346 and additional regions thereof do not include the first sacrificial fill material 346. In additional embodiments, the first sacrificial fill material 346 is formed within the first contact openings 340 without being formed in the associated lateral openings, such as when the remaining portions of the implanted regions 320 remain in the additional stadium structure 310 at the processing stage of FIG. 12. In some instances, voids (e.g., gaps, seams) are formed within the first sacrificial fill material 346 during fabrication of the microelectronic device structure 100. For example, the first sacrificial fill material 346 may include one or more of the voids during formation thereof within the first contact openings 340 exhibiting a high aspect ratio.

The sacrificial fill material 346 may, for example, be formed of and include silicon material, such as amorphous silicon and/or polycrystalline silicon. In some embodiments, the sacrificial fill material 346 is doped with one or more dopants, such as at least one N-type dopant (e.g., one or more of arsenic, phosphorous, antimony, and bismuth) or at least one P-type dopant (e.g., one or more of boron, aluminum, and gallium).

Referring next to FIG. 13, the sacrificial material 106 (FIG. 12) of the preliminary tiers 108 (FIG. 12) of the preliminary stack structure 102 (FIG. 12) may be selectively removed (e.g., exhumed) (e.g., through slots formed to vertically and horizontally extend through the preliminary stack structure 102 (FIG. 12)) to create voids between vertically neighboring (e.g., in the Z-direction) levels of the insulative material 104 of the preliminary stack structure 102. The voids may then be filled with conductive material 136 to form a stack structure 132 including tiers 138 respectively including a level of the conductive material 136 and level of the insulative material 104.

In some embodiments, the conductive material 136 is formed to include one or more of tungsten, titanium, ruthenium, aluminum, and molybdenum. In additional embodiments, the conductive material 136 is formed to include conductively doped polysilicon. In further embodiments, the conductive material 136 is substantially free of silicon. The conductive material 136 may be formed of and include a single (e.g., only one) material (e.g., only one elemental metal, only one single metal-containing material), or may be formed of and include multiple materials (e.g., multiple elemental metals, multiple metal-containing materials). The conductive material 136 may be substantially homogeneous, or may be heterogeneous. In some embodiments, the conductive material 136 is substantially homogeneous. In additional embodiments, the conductive material 136 is heterogeneous. Optionally, at least one liner material (e.g., at least one insulative liner material, at least one conductive liner materials) may be formed around the conductive material 136 of one or more tier 138 of the stack structure 132. The liner material may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). In some embodiments, the liner material comprises at least one conductive material employed as a seed material for the formation of the conductive material 136. In some embodiments, the liner material further includes high-K dielectric material. In additional embodiments, the liner material comprises titanium nitride (TiNₓ, such as TiN). In further embodiments, the liner material includes aluminum oxide (AlOₓ, such as Al₂O₃). As a non-limiting example, AlOₓ (e.g., Al₂O₃) may be formed directly adjacent the insulative material 104 of the tiers 138, TiNₓ (e.g., TiN) may be formed directly adjacent to the AlOₓ, and W may be formed directly adjacent the TiNₓ. For clarity and ease of understanding the description, the liner material is not illustrated in FIG. 13, but it will be understood that the liner material may be disposed around the conductive material 136 of the stack structure 132.

The conductive material 136 of at least one vertically lower tier 118 of the stack structure 132 may be employed as at least one lower select gate structure (e.g., at least one source-side select gate (SGS) structure) of the microelectronic device structure 100. In addition, the conductive material 136 of at least one vertically higher tier 138 of the stack structure 132 may be employed for upper select gate structures (e.g., drain-side select gate (SGD) structures) of the microelectronic device structure 100. Furthermore, the conductive material 136 of some of the tiers 138 may be employed for word line structures (e.g., local word line structures) of the microelectronic device structure 100.

Referring next to FIG. 14, the microelectronic device structure 100 may be subjected to a material removal process to selectively remove the sacrificial fill material 346 (FIG. 13) and form vertical openings extending vertically through the stack structure 132 (e.g., through the stack structure 132 to the conductive routing structures 401) and lateral openings continuous with the vertical openings. Subsequently, the vertical openings and the associated lateral openings may be substantially filled with conductive material to form first conductive contacts 350 (e.g., WL contacts, SGS contacts) including first portions 352 (e.g., vertical portions) extending vertically through the stack structure 132 (e.g., through the stack structure 132 to the conductive routing structures 401) and second portions 354 (e.g., lateral portions) integral and continuous (e.g., unitary) with the first portions 352. The second portions 354 of the first conductive contacts 350 may horizontally project outward from the first portions 352 of the first conductive contacts 350. For an individual first conductive contact 350, the second portion 354 thereof may be in physical contact with the insulative fill material 130, the conductive material 136 and the insulative material 104 of one of the tiers 138 of the stack structure 132 vertically proximate (e.g., directly vertically adjacent) the treads of an individual step 314 of the additional stadium structure 310. As shown in FIG. 14, each of the first conductive contacts 350 may be within a horizontal area of the tread of the individual step 314 of the additional stadium structure 310, although other configurations may be contemplated. Lateral dimension of the step 314 may be relatively larger than lateral dimensions of the first conductive contact 350 (including the first portion 352 and the second portion 354 thereof) operatively associated therewith.

At least some of the first conductive contacts 350 may exhibit a different geometric configuration (e.g., one or more different dimensions, a different shape) and/or different horizontal spacing than at least some other of the first conductive contacts 350. In some embodiments, the microelectronic device structure 100 is substantially free of conductive contacts that terminate on the additional steps 314 of the additional stadium structure 310.

The first conductive contacts 350 may be formed of and include conductive material. In some embodiments, the first conductive contacts 350 respectively comprise tungsten. The first conductive contacts 350 may or may not have substantially the same material composition as the conductive material 136 of the stack structure 132.

Each of the first conductive contacts 350 of the microelectronic device structure 100 may be formed to extend entirely through the vertical extent of the stack structure 132 and to terminate at the single vertical location in order to substantially reduce (e.g., substantially prevent) damage within the additional stadium structure 310 during fabrication. Accordingly, manufacturing processes may be simplified by forming the first conductive contacts 350 to extend entirely through the vertical extent of the stack structure 132 and to terminate at a single location (e.g., at or within the conductive routing structures 401), without forming the first conductive contacts 350 to extend to varying (e.g., differing) depths of the individual additional steps 314 of the additional stadium structure 310. In contrast, conventional microelectronic device structures include conductive contacts that terminate (e.g., land on) upper surfaces of individual steps of staircase structures, resulting in varying heights of conductive contacts throughout the staircase structures.

As shown in FIG. 14, relative to the second portion 354 of an individual first conductive contact 350, one or more side surfaces (e.g., lateral side surfaces, horizontal side surfaces) of the isolation regions 344 may directly contact side surfaces of the conductive material 136 of the tiers 128 of the stack structure 132 vertically underlying the second portion 354 of the first conductive contact 350. The isolation regions 344 electrically isolate the conductive material of an individual first conductive contact 350 from the conductive material 136 of different ones of the tiers 138 vertically underlying the second portion 354 of first conductive contact 350.

Accordingly, an individual first conductive contact 350 may be configured to facilitate electrical communication between an individual conductive routing structures 401 and the conductive material 136 of one of the tiers 138 horizontally neighboring and coupled to (e.g., unitary with, continuous with) the second portion 354 of the first conductive contact 350. Further, the second portion 354 of at least one of the first conductive contacts 350 is vertically offset from the second portion 354 of at least one other of the first conductive contacts 350. Forming the first conductive contacts 350 to individually facilitate electrical communication between one of the conductive routing structures 401 and the conductive material 136 of one of the tiers 138 of the stack structure 132 may reduce a quantity of support structures present within the WL contact region 300 as compared to conventional configurations. Accordingly, the stack structure 132, a greater quantity of the additional steps 314 of the additional stadium structure 310 may be provided within a given horizontal area as compared to conventional configurations. By providing the first conductive contact 350 within a horizontal area of the additional stadium structure 310, such configurations may permit reduced congestion in conductive routing pathways above the stack structure 132. By reducing congestion in conductive routing pathways above the stack structure 132, horizontal spacing of conductive features above the stack structure 132 may be increased, resulting in a decrease in parasitic (e.g., stray) capacitance between horizontally neighboring conductive features during use and operation of a microelectronic device of the disclosure.

In addition, by forming the first portions 352 and the second portions 354 of the first conductive contacts 350 at the same processing stage, the manufacturing processes may be simplified and costs may be reduced. The second portions 354 of the first conductive contacts 350 may be formed during (e.g., substantially simultaneous with) formation of the first portions 352 of the first conductive contacts 350 using a single, continuous CVD process or a single, continuous PVD process, for example, without forming the second portions 354 using an ALD process, similar to that used during the replacement gate process acts. Additionally, the methods and structures of the disclosure may reduce the risk of damage during the formation of devices of the disclosure and may effectuate increased yield and decreased current leakage (e.g., which may otherwise result from undesirable damage) as compared to conventional methods, conventional structures, and conventional devices.

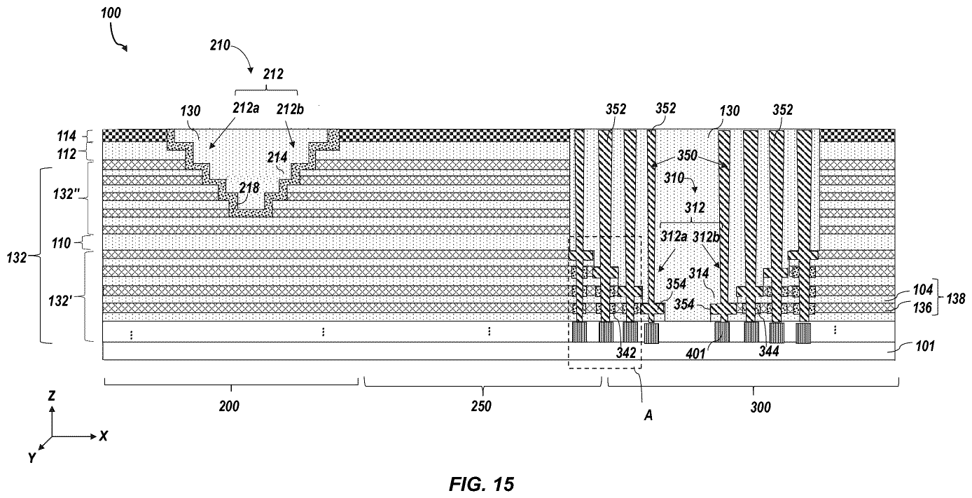

FIG. 15 is a simplified, partial vertical cross-sectional view of the microelectronic device structure 100 at the processing stage previously described with reference to FIG. 14. As shown, the stack structure 132 may include the lower stack structure 132′ (e.g., the lower deck), the upper stack structure 132″ (e.g., the upper deck) overlying the lower stack structure 132′, and the inter-deck structure 110 vertically between the lower stack structure 132′ (e.g., the lower deck), the upper stack structure 132″.

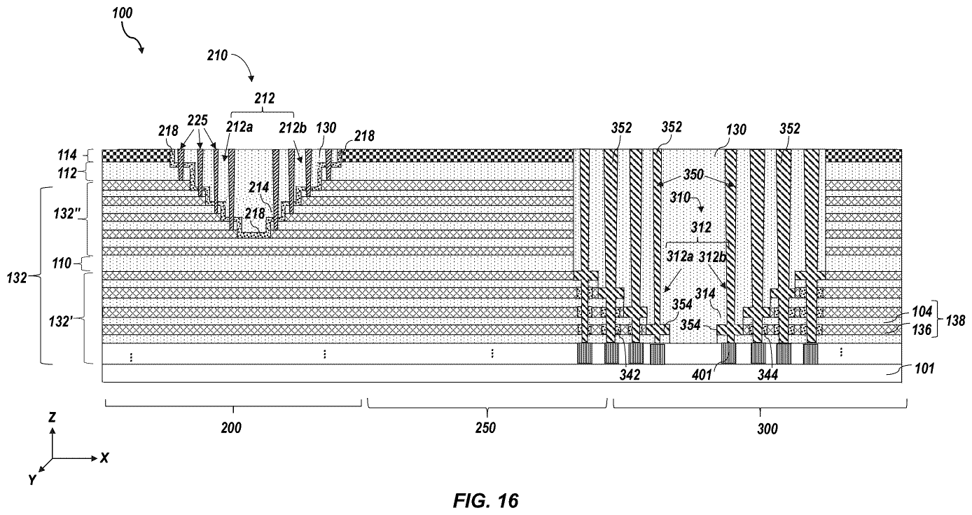

Referring next to FIG. 16, second conductive contacts 225 (e.g., SGD contacts) may be formed within the SGD contact region 200 to vertical extend through the isolative fill material 130 and the modified oxide liner material 218 to the conductive material 136 of at least some of the tiers 138 of the upper stack structure 132″ (e.g., upper deck) of the stack structure 132. The second conductive contacts 225 may be formed to vertically extend through the isolative fill material 130 and the modified oxide liner material 218 to contact (e.g., physically contact, electrically contact) the conductive material 136 of some of the tiers 138 at the steps 214 of one or more of the staircase structures 212 of the stadium structure 210 (e.g., SGD stadium structure) within the SGD contact region 200. Any desirable quantity and distribution of the second conductive contacts 225 may be formed within the horizontal area of on the stadium structure 210. For example, the second conductive contacts 225 may be formed on at least some of the steps 214 of the first staircase structure 212a and/or at least some of the steps 214 of the second staircase structure 212b of the stadium structure 210.

The second conductive contacts 225 may each individually be formed to exhibit a desired horizontal cross-sectional shape. In some embodiments, each of the second conductive contacts 225 is formed to exhibit a substantially circular horizontal cross-sectional shape. In additional embodiments, one or more (e.g., each) of the second conductive contacts 225 exhibits a non-circular cross-sectional shape, such as one more of an oblong cross-sectional shape, an elliptical cross-sectional shape, a square cross-sectional shape, a rectangular cross-sectional shape. In addition, each of the second conductive contacts 225 may be formed to exhibit substantially the same horizontal cross-sectional dimensions (e.g., substantially the same horizontal diameter), or at least one of the second conductive contacts 225 may be formed to exhibit one or more different horizontal cross-sectional dimensions (e.g., a different horizontal diameter) than at least one other of the second conductive contacts 225. In some embodiments, all of the second conductive contacts 225 are formed to exhibit substantially the same horizontal cross-sectional dimensions.

The second conductive contacts 225 may be formed of and include conductive material. As a non-limiting example, the second conductive contacts 225 may be formed of and include one or more of at least one metal, at least one alloy, and at least one conductive metal-containing material (e.g., a conductive metal nitride, a conductive metal silicide, a conductive metal carbide, a conductive metal oxide). A material composition of the second conductive contacts 225 may be substantially the same as a material composition of the conductive material 136 of the tiers 138 of the stack structure 132, or the material composition of the second conductive contacts 225 may be different than the material composition of the conductive material 136 of the tiers 138 of the stack structure 132. In some embodiments, the second conductive contacts 225 are individually formed of and include tungsten (W).

FIG. 17 illustrates a simplified, partial cutaway perspective view of a portion of a microelectronic device 501 (e.g., a memory device, such as a 3D NAND Flash memory device) including a microelectronic device structure 500. The microelectronic device structure 500 may be substantially similar to the microelectronic device structure 100 following the processing stage previously described with reference to FIG. 16. As shown in FIG. 17, the microelectronic device structure 500 may include a staircase structure 520 (e.g., corresponding to the additional stadium structure 310 of FIG. 16) defining contact regions for connecting first conductive contacts 506 (e.g., corresponding to the first conductive contacts 350 of FIG. 16) to conductive routing structures 518 (e.g., corresponding the conductive routing structures 401 of FIG. 16) and to conductive material 505 (e.g., corresponding to the conductive material 136 of FIG. 16) of tiers (e.g., corresponding to the tiers 138 of FIG. 16) of a stack structure (e.g., corresponding to the stack structure 132 of FIG. 16). The microelectronic device structure 500 may further include vertically extending strings 507 of memory cells 503 that are coupled to each other in series. The vertically extending strings 507 of memory cells 503 may extend vertically (e.g., in the Z-direction) and orthogonally to data lines 502, a source structure 504, first select gates 508 (e.g., upper select gates, drain select gates (SGDs)), select lines 509, and a second select gate 510 (e.g., a lower select gate, a source select gate (SGS)). The microelectronic device 501 may include multiple blocks 532 horizontally separated (e.g., in the Y-direction) from one another by filled slot structures 530.

Second conductive contacts 511 (e.g., corresponding to the second conductive contacts 225 of FIG. 16) may, optionally, electrically couple components to each other as shown. For example, the select lines 509 may be electrically coupled to the first select gates 508 by way of the second conductive contacts 511. The microelectronic device 501 may also include a control unit 512 positioned under and within a horizontal area of the memory array including the vertically extending strings 507 of memory cells 503. The control unit 512 may include control logic devices configured to control various operations of other features (e.g., the vertically extending strings 507 of memory cells 503) of the microelectronic device 501. By way of non-limiting example, the control unit 512 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control unit 512 may be coupled to the data lines 502, the source structure 504, the first conductive contacts 506 (e.g., corresponding to the first conductive contacts 350 of FIG. 16), the first select gates 508, and the second select gates 510, without limitation. In some embodiments, the control unit 512 includes CMOS (complementary metal-oxide-semiconductor) circuitry. In such embodiments, the control unit 512 may be characterized as having a “CMOS under Array” (“CuA”) configuration, wherein the CMOS circuitry of a logic region is at least partially (e.g., substantially) positioned within horizontal areas of memory array regions of a microelectronic device 501. Additional conductive routing structures 517 may couple components (e.g., the first conductive contacts 506, the conductive routing structures 518) to circuitry of the control unit 512.

The first select gates 508 may extend horizontally in a first direction (e.g., the X-direction) and may be coupled to respective first groups of vertical strings 507 of memory cells 503 at a first end (e.g., an upper end) of the vertical strings 507. The second select gate 510 may be coupled to the vertical strings 507 at a second, opposite end (e.g., a lower end) of the vertical strings 507 of memory cells 503.

The data lines 502 (e.g., digit lines, bit lines) may extend horizontally in a second direction (e.g., in the Y-direction) that is at an angle (e.g., perpendicular) to the first direction in which the first select gates 508 extend. The data lines 502 may be electrically coupled to the vertical strings 507 through conductive contact structures 534. Individual data lines 502 may be coupled to individual groups of the vertical strings 507 extending the second direction (e.g., the Y-direction) at the first end (e.g., the upper end) of the vertical strings 507 of the individual groups. Additional individual groups of the vertical strings 507 extending the first direction (e.g., the X-direction) and coupled to individual first select gates 508 may share a particular vertical string 507 thereof with individual group of vertical strings 507 coupled to an individual data line 502. Thus, an individual vertical string 507 of memory cells 503 may be selected at an intersection of an individual first select gate 508 and an individual data line 502. Accordingly, the first select gates 508 may be used for selecting memory cells 503 of the vertical strings 507 of memory cells 503.

The conductive material 505 (e.g., corresponding to the conductive material 136 of the microelectronic device structure 100) may extend in respective horizontal planes. The conductive material 505 may be stacked vertically, such that each conductive material 505 is coupled to at least some of the vertical strings 507 of memory cells 503, and the vertical strings 507 of the memory cells 503 extend vertically through the stack structure including the conductive material 505. The conductive material 505 may be coupled to or may form control gates of the memory cells 503.

The first select gates 508 and the second select gates 510 may operate to select a vertical string 507 of the memory cells 503 interposed between data lines 502 and the source structure 504. Thus, an individual memory cell 503 may be selected and electrically coupled to a data line 502 by operation of (e.g., by selecting) the appropriate first select gate 508, second select gate 510, and conductive material 505 that are coupled to the particular memory cell 503.

Thus, in accordance with embodiments of the disclosure, a method of forming a microelectronic device includes forming a staircase structure within an upper portion of a preliminary stack structure. The preliminary stack structure comprises preliminary tiers respectively including insulative material and sacrificial vertically neighboring the insulative material. The staircase structure has steps defined by edges of an upper group of the preliminary tiers. An oxide liner material is formed on the steps of the staircase structure. After forming the oxide liner material, an additional staircase structure is formed within a lower portion of the preliminary stack structure. The additional staircase structure having additional steps defined by edges of a lower group of the preliminary tiers. Implanted regions are formed within portions of the sacrificial material of the preliminary tiers of the lower group of the preliminary tiers proximate the additional steps of the additional staircase structure. The method also includes forming contact openings within horizontal areas of the additional steps of the additional staircase structure, and replacing the sacrificial material of the preliminary tiers of the preliminary stack structure with conductive material to form a stack structure. Conductive contacts are formed within the contact openings and vertically extending through an entire height of the stack structure. Additional conductive contacts are formed within horizontal areas of and vertically extending to the steps of the staircase structure.

Furthermore, in accordance with additional embodiments of the disclosure, a microelectronic device includes a stack structure comprising a vertically alternating sequence of conductive material and insulative material arranged in tiers. The stack structure includes a select gate drain (SGD) contact region and a word line (WL) contact region horizontally neighboring the SGD contact region. The microelectronic device also includes an oxide liner on a staircase structure within a horizontal area of the SGD contact region. The oxide liner includes a dielectric oxide material doped with one or more of boron, carbon, oxygen, and gallium. The microelectronic device further includes an conductive contacts within a horizontal area of an additional staircase structure within the WL contact region, and additional conductive contacts within a horizontal area of the staircase structure within the SGD contact region. The conductive contacts extend vertically through an entire height of the stack structure and respectively coupled to the conductive material of a respective one of the tiers of the stack structure within a vertical span of the additional staircase structure. The additional conductive contacts respectively extend vertically to in contact with the conductive material of an additional respective one of the tiers of the stack structure within a vertical span of the staircase structure.

In accordance with further embodiments of the disclosure, a memory device includes a stack structure comprising a lower deck and an upper deck vertically overlying the lower deck. The lower deck includes tiers vertically stacked relative to one another and respectively including conductive material and insulative material vertically neighboring the conductive material. The lower deck also includes a stadium structure comprising opposing staircase structures respectively having steps comprising horizontal ends of at least some of the tiers. The upper deck of the stack structure includes additional tiers vertically stacked relative to one another and respectively including the conductive material and the insulative material vertically neighboring the conductive material. The upper deck also includes an additional stadium structure comprising additional opposing staircase structures respectively having additional steps comprising horizontal ends of at least some of the additional tiers. The memory device includes strings of memory cells vertically extending through the lower deck and the upper deck of the stack structure. The memory device also includes a doped dielectric oxide material within the upper deck of the stack structure and on the additional opposing staircase structures of the additional stadium structure. The memory device further includes first contact structures within a horizontal area of the stadium structure of the lower deck of the stack structure, and the second contact structures within a horizontal area of the additional stadium structure of the upper deck of the stack structure. The first contact structures respectively vertically extend completely through the upper deck and the lower deck of the stack structure and coupled to the conductive material of a respective one of the tiers of the lower deck. The second contact structures respectively vertically extending through the doped dielectric oxide material and coupled to the conductive material of a respective one of the additional tiers of the upper deck.

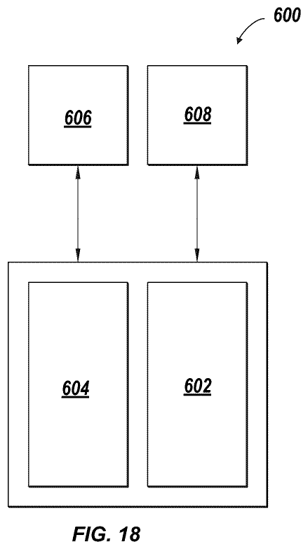

Microelectronic devices (e.g., the microelectronic device 501 of FIG. 17) including microelectronic device structures (e.g., the microelectronic device structure 100 of FIG. 16) of the disclosure may be included in embodiments of electronic systems of the disclosure. For example, FIG. 18 is a schematic block diagram of an electronic system 600, in accordance with embodiments of the disclosure. The electronic system 600 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 600 includes at least one memory device 602. The memory device 602 may include, for example, an embodiment of a microelectronic device structure (e.g., the microelectronic device structure 100 of FIG. 16) and/or a microelectronic device (e.g., the microelectronic device 501 of FIG. 17) previously described herein.

The electronic system 600 may further include at least one electronic signal processor device 604 (often referred to as a “microprocessor”). The electronic signal processor device 604 may, optionally, include an embodiment of one or more of a microelectronic device and a microelectronic device structure previously described herein. The electronic system 600 may further include one or more input devices 606 for inputting information into the electronic system 600 by a user, such as, for example, a mouse or other pointing device, a keyboard, a touchpad, a button, or a control panel. The electronic system 600 may further include one or more output devices 608 for outputting information (e.g., visual or audio output) to a user such as, for example, a monitor, a display, a printer, an audio output jack, a speaker, etc. In some embodiments, the input device 606 and the output device 608 may comprise a single touchscreen device that can be used both to input information to the electronic system 600 and to output visual information to a user. The input device 606 and the output device 608 may communicate electrically with one or more of the memory device 602 and the electronic signal processor device 604.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A method of forming a microelectronic device, comprising:
forming a staircase structure within an upper portion of a preliminary stack structure comprising preliminary tiers respectively including insulative material and sacrificial material vertically neighboring the insulative material, the staircase structure having steps defined by edges of an upper group of the preliminary tiers;
forming an oxide liner material on the steps of the staircase structure;
after forming the oxide liner material, forming an additional staircase structure within a lower portion of the preliminary stack structure, the additional staircase structure having additional steps defined by edges of a lower group of the preliminary tiers;
forming implanted regions within portions of the sacrificial material of the preliminary tiers of the lower group of the preliminary tiers proximate the additional steps of the additional staircase structure;
forming contact openings within horizontal areas of the additional steps of the additional staircase structure;
replacing the sacrificial material of the preliminary tiers of the preliminary stack structure with conductive material to form a stack structure;
forming conductive contacts within the contact openings and vertically extending through an entire height of the stack structure; and
forming additional conductive contacts within horizontal areas of and vertically extending to the steps of the staircase structure.

2. The method of claim 1, wherein forming the contact openings within the horizontal areas of the additional steps of the additional staircase structure comprises:
forming a first portions of respective ones of the contact openings to vertically extend completely through the preliminary stack structure; and
forming a second portion of the respective ones of the contact openings in communication with and outwardly horizontally projecting from the first portion of the openings, the second portion positioned within a horizontal area of a respective one of the additional steps of the additional staircase structure.

3. The method of claim 1, wherein forming the implanted regions comprises substantially confining respective ones of the implanted regions to:
a horizontal area of a respective one of the additional steps of the additional staircase structure; and
a vertical span of the sacrificial material of a respective one of the preliminary tiers defining the respective one of the additional steps of the additional staircase structure.

4. The method of claim 1, wherein forming the implanted regions comprises implanting one or more of boron, carbon, oxygen, and gallium into the sacrificial material of the preliminary tiers of the lower group of the preliminary tiers.

5. The method of claim 4, further comprising implanting the one or more of boron, carbon, oxygen, and gallium into the oxide liner material on the steps of the staircase structure.

6. The method of claim 4, further comprising forming each of the implanted regions to comprise a concentration of the boron, carbon, oxygen, and gallium within a range of from about 0.1 atomic % to about 25 atomic %.

7. The method of claim 1, wherein replacing the sacrificial material of the preliminary tiers of the preliminary stack structure with conductive material comprises removing the sacrificial material of the preliminary tiers of the preliminary stack structure as well as doped sacrificial material within the implanted regions.

8. The method of claim 1, wherein forming contact openings within horizontal areas of the additional steps of the additional staircase structure comprises:
forming initial contact openings vertically extending completely through the preliminary stack structure; and
horizontally recessing portions of the sacrificial material of respective ones of the preliminary tiers within a vertical span of the additional staircase structure and horizontally adjacent to the initial contact openings to form lateral recesses continuous with and outwardly horizontally projection from the initial contact openings.

9. The method of claim 8, further comprising forming an insulative liner material within the lateral recesses prior to replacing the sacrificial material of the preliminary tiers of the preliminary stack structure with the conductive material.

10. The method of claim 1, wherein forming the additional conductive contacts comprises forming each of the additional conductive contacts to vertically extend through the oxide liner material on the steps of the staircase structure.

11. A microelectronic device, comprising:
a stack structure comprising a vertically alternating sequence of conductive material and insulative material arranged in tiers, the stack structure including a select gate drain (SGD) contact region and a word line (WL) contact region horizontally neighboring the SGD contact region;
an oxide liner on a staircase structure within a horizontal area of the SGD contact region, the oxide liner including a dielectric oxide material doped with one or more of boron, carbon, oxygen, and gallium;
conductive contacts within a horizontal area of an additional staircase structure within the WL contact region, the conductive contacts extending vertically through an entire height of the stack structure and respectively coupled to the conductive material of a respective one of the tiers of the stack structure within a vertical span of the additional staircase structure; and
additional conductive contacts within a horizontal area of the staircase structure within the SGD contact region, the additional conductive contacts respectively extending vertically to in contact with the conductive material of an additional respective one of the tiers of the stack structure within a vertical span of the staircase structure.

12. The microelectronic device of claim 11, wherein the oxide liner comprises a different material composition than that of the insulative material of the tiers of the stack structure.

13. The microelectronic device of claim 12, wherein a concentration of the one or more of boron, carbon, oxygen, and gallium within the oxide liner is within a range of from about 0.1 atomic % to about 25 atomic %.

14. The microelectronic device of claim 11, wherein the conductive contacts individually comprise:
a first portion vertically extending completely through the stack structure; and
a second portion outwardly horizontally projecting from and unitary with the first portion, the second portion substantially confined within a horizontal area of a respective step of the additional staircase structure.

15. The microelectronic device of claim 14, further comprising an insulative liner material horizontally interposed between the first portion of a respective one of the conductive contacts and additional ones of the tiers of the stack structure vertically underlying the respective one of the tiers of the stack structure within the vertical span of the additional staircase structure.

16. The microelectronic device of claim 11, further comprising conductive routing structures vertically underlying the stack structure and in physical contact with bottom surfaces of the conductive contacts.

17. The microelectronic device of claim 11, wherein the conductive contacts within the WL contact region all have substantially a same vertical height as one another.

18. A memory device, comprising:
a stack structure comprising:
a lower deck comprising:
tiers vertically stacked relative to one another and respectively including conductive material and insulative material vertically neighboring the conductive material; and
a stadium structure comprising opposing staircase structures respectively having steps comprising horizontal ends of at least some of the tiers;
an upper deck vertically overlying the lower deck and comprising:
additional tiers vertically stacked relative to one another and respectively including the conductive material and the insulative material vertically neighboring the conductive material; and
an additional stadium structure comprising additional opposing staircase structures respectively having additional steps comprising horizontal ends of at least some of the additional tiers;
strings of memory cells vertically extending through the lower deck and the upper deck of the stack structure;
a doped dielectric oxide material within the upper deck of the stack structure and on the additional opposing staircase structures of the additional stadium structure;
first contact structures within a horizontal area of the stadium structure of the lower deck of the stack structure, the first contact structures respectively vertically extending completely through the upper deck and the lower deck of the stack structure and coupled to the conductive material of a respective one of the tiers of the lower deck; and
second contact structures within a horizontal area of the additional stadium structure of the upper deck of the stack structure, the second contact structures respectively vertically extending through the doped dielectric oxide material and coupled to the conductive material of a respective one of the additional tiers of the upper deck.

19. The memory device of claim 18, wherein first contact structures respectively comprise:
a first portion vertically extending completely through the lower desk and the upper deck of the stack structure; and
a second portion outwardly horizontally projecting from the first portion and positioned at a vertical elevation of the conductive material of the respective one of the tiers of the lower deck.

20. The memory device of claim 19, wherein second contact structures respectively have a lowermost boundary with a vertical span of the additional stadium structure of the upper deck of the stack structure.
